(19) United States
(12) Patent Application Publication
(10) Pub. No.: US 2011/0303535 A1
(43) Pub. Date: Dec. 15, 2011

(54) SPUTTERING TARGETS AND METHODS OF FORMING THE SAME

(76) Inventors: Steven A. Miller, Canton, MA (US); Prabhat Kumar, Framingham, MA (US); Mark Confroy, Solon, OH (US); Richard McCorry, Rochester Hills, MI (US); Gary Rozak, Akron, OH (US); Peter Jepson, Newbury, MA (US)

(21) Appl. No.: 13/173,412

(22) Filed: Jun. 30, 2011

Related U.S. Application Data
(63) Continuation-in-part of application No. 11/937,164, filed on Nov. 8, 2007.
(60) Provisional application No. 60/915,967, filed on May 4, 2007.

(51) Int. Cl. C23C 14/34; B05D 5/00; B05D 1/02; B32B 38/08; C23C 14/14; B05D 1/36

(52) U.S. Cl. 204/298.13; 204/298.12; 427/402; 427/421.1; 156/278; 427/256

(57) ABSTRACT

In various embodiments, sputtering targets incorporate an intermediate plate having a coefficient of thermal expansion (CTE) between a CTE of the backing plate and a CTE of the target material.

### RELATED APPLICATIONS

This application is a continuation-in-part of U.S. Ser. No. 11/937,164, filed Nov. 8, 2007, which claims the benefit of and priority to U.S. Provisional Patent Application No. 60/915,967, filed May 4, 2007, the entire disclosure of each of which is hereby incorporated herein by reference.

### FIELD OF THE INVENTION

In various embodiments, the present invention relates to sputtering targets, and more particularly, to sputtering targets having low residual stress.

### BACKGROUND

Sputtering targets typically include a target layer of the desired material for, e.g., physical vapor deposition (PVD), bonded to a high-thermal-conductivity backing plate (made of, e.g., copper). The physical properties of sputtering targets employed in the electronics industry greatly influence the final properties of the deposited thin films. Thus, it is desirable for sputtering targets to have one or more of the following properties in order to enable and enhance the manufacture of high-quality thin-film devices and circuitry: (1) fine and uniform grain structure, (2) random and uniform crystallographic orientation of individual grains, (3) a microstructure that is substantially invariant (on the macroscale) throughout the body of the target, (4) a microstructure repeatable from target to target, and (5) a microstructure that has approximately 100% density with high-strength intergranular bonding.

The properties listed above are very difficult to attain in tantalum and niobium targets, as high-purity tantalum and niobium are typically refined and purified via electron-beam melting and casting into a cold, water-cooled mold. The ingot thus formed typically has many extremely large (i.e., greater than 1 cm in both width and length) grains, and may require extensive and costly thermomechanical processing to reduce the grain size and reduce the crystallographic alignment of the individual grains (i.e., reduce the texture of the material). However, such thermomechanical processing is limited in its ability to reduce grain size, randomize crystallography, and produce uniform microstructure. Typically, tantalum sputtering-target material produced from the ingot still contains a large degree of nonuniformity (i.e., grain-size and texture-banding regions having a grain size and texture atypical of the overall grain size and texture of the target as a whole).

The rejuvenation or reprocessing or repair of used targets is also of economical interest due to the fact that refractory metals such as tantalum, as well as the processes for bonding such materials to backing plates, are quite expensive. The expense is compounded by the fact that only about 25-30% of a planar target and 60-70% of a rotary target are typically used in sputtering before the entire target is replaced.

Spray deposition (i.e., of metal powder) is one family of techniques that has been proposed for the fabrication and rejuvenation of sputtering targets, although such techniques are plagued with various issues, particularly when utilized for refractory metal-based sputtering targets. Specifically, most thermal-spray-based techniques involve melting of the metal powder to be deposited at temperatures far above the melting points of typical backing plate materials. Furthermore, sputtering targets spray-deposited at lower temperatures often exhibit high levels of residual stress that result in deleterious deformation and/or debonding of the target. Thus, there is a need for an economical method of forming and repairing sputtering targets (particularly those incorporating refractory metals) that minimizes or eliminates such residual stresses.

### SUMMARY

In accordance with embodiments of the present invention, sputtering targets incorporate an intermediate plate or layer of material between the material to be sputtered (typically a refractory metal) and the conventional backing plate (typically including or consisting essentially of copper, aluminum, etc.). The intermediate layer and/or the target layer are typically spray deposited by, e.g., cold spray or kinetic spray. Cold spray generally employs a high-velocity gas jet to rapidly accelerate powders, which typically are less than approximately 44 microns in size, to high velocity. When the powder strikes a surface, it bonds to the surface to form an integral, well-bonded and dense coating. Cold spray is performed without heating the powder to a temperature near or above its melting point as is done with traditional thermal-spray processes. Low-temperature-formed cold-sprayed coatings have many advantages, including lack of oxidation, high density, solid-state compaction, the lack of thermally induced stresses and the lack of substantial substrate heating.

Kinetic spray involves, for example, injecting starting powders having particle diameters greater than 65 microns into a de Laval-type nozzle, where they are entrained in a supersonic gas stream and accelerated to high velocities due to drag effects. The kinetic energy of the particles is transformed via plastic deformation into strain and heat on impact with the substrate surface. Because cold and kinetic spray do not substantially heat the powder, they may be used to make targets directly on the backing plate as well as repair used targets without removing the target from the backing plate.

The intermediate plate is typically formed of a material having a higher melting point than the backing plate but that is less expensive than more exotic refractory metals such as tantalum. In various embodiments, the intermediate plate has a coefficient of thermal expansion between those of the target material and the backing plate. The intermediate plate may, in some embodiments, have a profiled shape, i.e., include recesses in regions of greatest material consumption during PVD. Thus, greater amounts of the target material may be provided in the areas of greatest consumption, and the amount of (typically expensive) target material in other areas may be minimized. The intermediate layer may include or consist essentially of materials such as niobium, titanium, and/or alloys of the target material and a backing-plate material.

In one aspect, embodiments of the invention feature a method of forming a sputtering target that includes or consists essentially of providing an intermediate plate on a backing plate and forming a target material on the intermediate plate. The intermediate plate has a coefficient of thermal expansion (CTE) between the CTE of the backing plate and the CTE of the target material.

Embodiments of the invention may include one or more of the following in any of a variety of combinations. The intermediate plate may be formed on the backing plate and/or the target material may be formed on the intermediate plate by spray deposition, e.g., cold spray. Providing the intermediate plate may include or consist essentially of bonding the intermediate plate to the backing plate. The target material may be formed on the intermediate plate prior to the intermediate plate being bonded to the backing plate, and/or the target material may be formed by spray deposition, e.g., cold spray. The top surface of the intermediate plate may have a profiled surface contour including one or more recesses corresponding to regions of high target-material consumption during a physical-vapor-deposition process.

Forming the target material on the intermediate plate may include or consist essentially of forming the target material on a substrate, releasing the target material from the substrate, and bonding the target material to the intermediate plate. The target material may be formed by spray deposition, e.g., cold spray. The substrate may include or consist essentially of a release layer to facilitate release of the target material from the substrate.

In another aspect, embodiments of the invention feature a sputtering target including or consisting essentially of a backing plate, a target material disposed over the backing plate, and an intermediate plate disposed between the backing plate and the target material. The backing plate includes or consists essentially of a backing-plate material, and the melting point of the target material exceeds the melting point of the backing plate by at least 500° C. The intermediate plate has a CTE between the CTE of the backing plate and the CTE of the target material.

Embodiments of the invention may include one or more of the following in any of a variety of combinations. The target material and/or the intermediate plate may include or consist essentially of unmelted metal powder. The target material may include or consist essentially of niobium, tantalum, tungsten, molybdenum, zirconium, titanium, and/or an alloy thereof. The intermediate plate may include or consist essentially of an alloy of the backing-plate material and the target material. The target material may have a substantially random crystalline texture. The backing-plate material may include or consist essentially of copper, aluminum, or an alloy of beryllium with copper and/or aluminum. The target material may be substantially free of grain-size banding and texture banding and/or may have a substantially uniform equiaxed grain structure and an average grain size less than 44 microns. The top surface of the intermediate plate may have a profiled surface contour including one or more recesses corresponding to regions of high target-material consumption during a physical-vapor-deposition process.

These and other objects, along with advantages and features of the invention, will become more apparent through reference to the following description, the accompanying drawings, and the claims. Furthermore, it is to be understood that the features of the various embodiments described herein are not mutually exclusive and can exist in various combinations and permutations. As used herein, the term “substantially” means ±10%, and, in some embodiments, ±5%. The term “consists essentially of” means excluding other materials that contribute to function, unless otherwise defined herein. Nonetheless, such other materials may be present, collectively or individually, in trace amounts.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 is a schematic cross-section of a sputtering target designed and formed in accordance with various embodiments of the invention;

FIGS. 2A and 2B are schematic cross-sections of a method of forming a target material for a sputtering target in accordance with various embodiments of the invention; and

FIGS. 3A and 3B are, respectively, schematic cross-sections of a depleted sputtering target and a refurbished sputtering target in accordance with various embodiments of the invention.

### DETAILED DESCRIPTION

Embodiments of the present invention enable direct fabrication of sputtering targets without the complex processing generally required via the manufacture of targets having the desired microstructure and properties (e.g., as detailed above) directly on a backing plate or an intermediate plate (that is then bonded to a backing plate). Various embodiments also enable the repair of used targets simply with or without the prior removal of the used target from the backing plate. The target material is initially provided as a powder that is deposited on the backing plate or intermediate plate without experiencing temperatures above the melting point of the powder. For example, the powder may be deposited by cold spray or kinetic spray. The powder typically includes or consists essentially of a refractory metal such as tantalum. In some embodiments, the intermediate plate is spray deposited directly on the backing plate.

The spray-deposition techniques utilized in various embodiments of the invention utilize an inert gas (e.g., argon, helium, nitrogen, and/or mixtures thereof) that is mixed with and accelerates the metal powder. However, in other embodiments, air is used. Hydrogen or mixtures of hydrogen with other gases may also be used advantageously due to hydrogen's extremely high sonic velocity. The sonic velocity of hydrogen is approximately 30% greater than that of helium, which in turn has a sonic velocity approximately three times that of nitrogen. The air sonic velocity is 344 m/s at 20° C. and 1 atmosphere (atm), while hydrogen has a sonic velocity of 1308 m/s.

In a preferred embodiment, the spraying includes or consists essentially of the steps of: (1) providing a spraying orifice adjacent the surface to be coated, (2) supplying to the spraying orifice a powder of a particulate material (preferably under pressure) of niobium, tantalum, tungsten, molybdenum, titanium, zirconium, and/or mixtures of at least two thereof or alloys thereof with one another or other metals, the powder having a particle size of 0.5 to 150 microns, preferably 5 to 80 microns, and most preferably 10 to 44 microns, and (3) supplying an inert gas at an elevated stagnation pressure to the spraying orifice, thus forming a spray of the particulate material and the gas onto the surface. The spraying orifice may be located in a region of low ambient pressure, e.g., a pressure substantially less than the stagnation pressure before the spraying orifice, in order to accelerate the spray. The coating may be substantially dense upon spraying, or may be densified during a post-spray annealing step at elevated temperature. The spraying may be performed with a cold spray gun, which may (along with the surface to be coated) be located within an inert ambient at pressures of, e.g., below 80 kPa, or above 0.1 Mpa. Cold spraying may be performed in accordance with U.S. Pat. No. 5,302,414, the entire disclosure of which is incorporated by reference herein.

Herein, references to cold spray should be interpreted as also including kinetic spray, and/or any other spray-deposition techniques in which a sprayed powder does not melt during spraying and deposition onto a surface. For example, a kinetic-spray process may utilize larger particles (e.g., between 65 and 200 microns) and higher powder temperatures than cold spray. Kinetic spray may also utilize a longer spray nozzle (e.g., approximately 280 mm) than a cold-spray nozzle (e.g., approximately 80 mm), as well as higher gas temperature (e.g., greater than approximately 200° C. but below the melting point of the sprayed powder).

In general, refractory metals utilized in accordance with embodiments of the invention have a purity (based on, e.g., metallic impurities) of at least 99%, e.g., at least 99.5%, at least 99.7%, at least 99.9%, at least 99.95%, at least 99.995%, at least 99.999%, or preferably at least 99.9995%. In general, alloys utilized in embodiments of the invention (at least a refractory-metal component, if present) also preferably have the above purity levels. In various embodiments, the total content of non-metallic impurities in the powder, such as oxygen, carbon, nitrogen, and/or hydrogen, is less than 1,000 ppm, preferably less than 500 ppm, and more preferably less than 150 ppm. In a preferred embodiment, the oxygen content is 50 ppm or less, the nitrogen content is 25 ppm or less and the carbon content is 25 ppm or less. The content of metallic impurities is advantageously 500 ppm or less, preferably 100 ppm or less and most preferably 50 ppm or less, in particular 10 ppm or less. Such metal powders may be purchased commercially or prepared by reduction of refractory-metal compounds with a reducing agent and, preferably, subsequent deoxidation.

Sputtering targets fabricated in accordance with embodiments of the present invention generally have a uniformly fine and crystallographically random microstructure throughout the entire thickness of the target material (and/or any intermediate plate formed by spray deposition). The sputtering targets preferably have a uniform grain structure in which each grain is less than approximately 44 microns in size and that has no preferred texture (i.e., consists essentially of randomly oriented grains) as measured by, e.g., electron back-scattered diffraction measurements. Moreover, the sputtering targets preferably exhibit substantially no grain-size or texture banding throughout the thickness of the target material. The purities and/or oxygen contents of the target material (and/or the intermediate plate) of sputtering targets fabricated in accordance with embodiments of the invention preferably are substantially equal to those of the starting powder(s) from which they are formed (i.e., preferably differ by no more than approximately 5%, or even no more than approximately 1%).

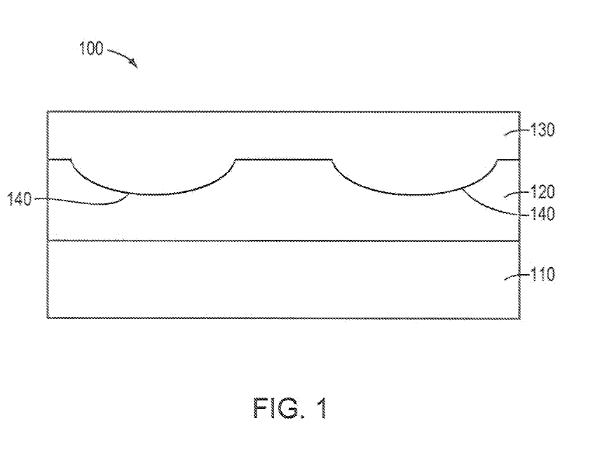

FIG. 1 depicts a sputtering target 100 designed and fabricated in accordance with embodiments of the present invention. Sputtering target 100 typically includes or consists essentially of a backing plate 110, an intermediate plate 120, and a target material 130. Plates 110, 120, and intermediate plate 120 and target material 130, may be (and typically are) in direct contact with each other, and may be dimensionally congruent (i.e., have substantially the same edge-to-edge dimensions). The backing plate 110 generally includes or consists essentially of a material with a high thermal conductivity, e.g., copper, aluminum, and/or alloys of copper and/or aluminum with beryllium. As such, backing plate 110 typically has a melting point lower (e.g., at least 200° C., at least 500° C., or even at least 1000° C. lower) than that of intermediate plate 120 and/or target material 130. In some embodiments, backing plate 110 features channels within its volume, through which a coolant (e.g., water) may be directed during PVD in order to dissipate heat from sputtering target 100. The backing plate 110 (and therefore also the sputtering target 100) may be in the form of a flat sheet (as depicted in FIG. 1), a rod, a cylinder, a block, or any other desired shape. Additional structural components, liquid cooling coils, a coolant reservoir, and/or complex flanges or other mechanical or electrical structures may also be attached to backing plate 110 and/or sputtering target 100.

The target material 130 typically includes or consists essentially of one or more metals or metal alloys, and in preferred embodiments includes or consists essentially of one or more refractory metals, e.g., niobium, molybdenum, tantalum, tungsten, and/or rhenium. Other metals that may be used in accordance with embodiments of the present invention include titanium, zirconium, chromium, and/or vanadium. The target material 130 generally has a large coefficient-of-thermal-expansion (CTE) mismatch with the backing plate 110 and/or may exhibit high levels of residual stress and/or warpage if spray-deposited directly on a backing plate 110.

In various embodiments of the present invention, the intermediate plate 120 (i) mitigates CTE mismatch between the target material 130 and the backing plate 110, (ii) provides significant reductions in the cost of sputtering target 100 (when compared to, e.g., a sputtering target consisting essentially of a refractory-metal target material directly on a conventional backing plate), and/or (iii) minimizes or eliminates residual stresses and/or warpage within sputtering target 100. Intermediate plate 120 may have a CTE between those of backing plate 110 and target material 130, and may even include or consist essentially of a mixture or alloy of the materials from which the backing plate 110 and target material 130 are formed. The melting point of the intermediate plate 120 is also generally between those of backing plate 110 and target material 130, and may be greater than the melting point of the backing plate 110 by at least, e.g., 500° C. In preferred embodiments, intermediate plate 120 includes or consists essentially of niobium, titanium, nickel, and/or stainless steel.

As depicted in FIG. 1, intermediate plate 120 may have a “profiled” surface contour or topology, i.e., include one or more recesses 140 in regions of greatest material consumption during PVD. Thus, greater amounts of the target material 130 may be provided in the areas of greatest consumption while maintaining a substantially flat exposed surface thereof, and the sputtering target 100 may be utilized for PVD for a longer term of service prior to refurbishment or replacement. In other embodiments, intermediate plate 120 has a substantially flat surface.

In various embodiments, the intermediate plate 120 is spray deposited (via, e.g., cold spray) directly on the backing plate 110. Thus, intermediate plate 120 may include or consist essentially of one or more layers of unmelted metal powder. Recesses 140 may be formed during the spray deposition by, e.g., the spraying of additional material therebetween. In such embodiments, the spraying process and apparatus may be computer-controlled based on a desired three-dimensional contour (including recesses 140). In other embodiments, intermediate plate 120 is fabricated with a substantially flat top surface. Such flat top surfaces may be utilized directly in finished sputtering targets 100, as mentioned above, or may be post-spray machined to incorporate one or more desired recesses 140. Target material 130 may then be formed directly on intermediate plate 120 by spray deposition, e.g., cold spray. The target material 130 substantially fills any recesses 140, and, as depicted in FIG. 1, has a substantially flat top surface upon completion. The relatively low temperatures utilized in spray-deposition processes (for intermediate plate 120 and/or target material 130) in accordance with various embodiments at least substantially prevents melting and/or other damage to backing plate 110. The spray-deposition process may be performed in an inert atmosphere (e.g., by disposing the spray apparatus and backing plate 110 and/or intermediate plate 120 within a vessel substantially free of oxygen and/or containing an atmosphere of one or more inert gases such as argon) and/or with an inert gas (e.g., argon, helium) as the supersonic jet that accelerates the powder during deposition.

In various other embodiments, target material 130 is formed over intermediate plate 120 prior to the attachment of intermediate plate 120 to backing plate 110. In such embodiments, the intermediate plate 120 may be formed via other conventional means, e.g., casting or rolling. Target material 130 may be spray deposited directly on the top surface of intermediate plate 120 (as detailed above). Then, the back surface of intermediate plate 120 is bonded to the backing plate 110 via, e.g., use of an intermediate bonding material such as indium or solder (or other low-melting-point metal or metal alloy) and/or a conductive epoxy (e.g., silver epoxy). Other bonding techniques that may be utilized in accordance with embodiments of the invention include diffusion bonding. The bond between intermediate plate 120 and backing plate 110 enables efficient conduction of heat therethrough in order to, e.g., prevent overheating of sputtering target 100 during PVD.

In either of the formation processes for the intermediate plate 120 described above, the presence of the intermediate plate 120 between the target material 130 and the backing plate 110 substantially minimizes or eliminates warpage and/or other distortions due to any residual stress in the target material 130 and/or CTE mismatch between the target material 130 and the backing plate 110. After deposition of target material 130, it may be mechanically ground and/or polished if less surface roughness is desired.

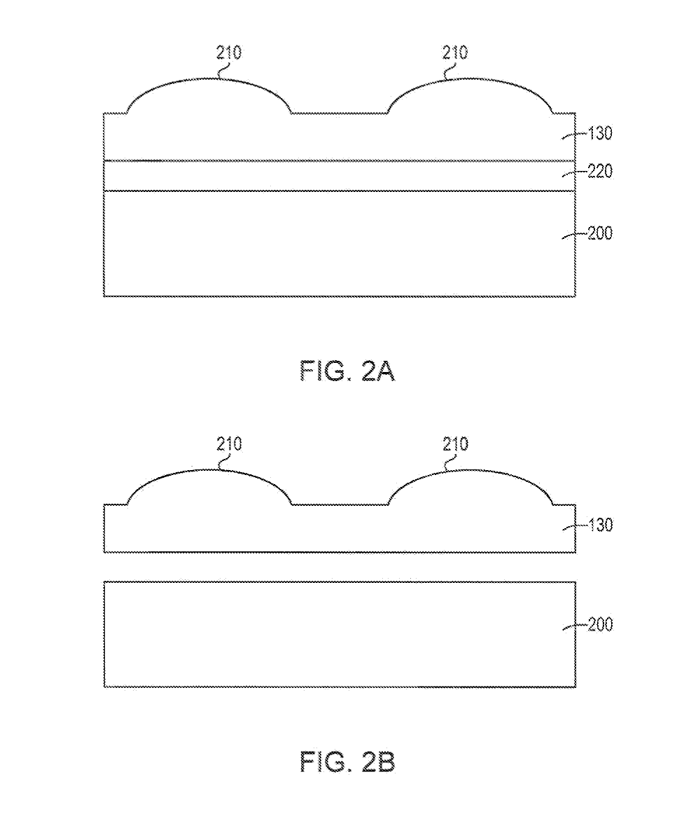

In some embodiments, the target material 130 is not spray deposited directly on intermediate plate 120. Rather, target material 130 is formed on a temporary substrate and with a shape complementary to that of intermediate plate 120 (including e.g., any recesses 140), and then the target material 130 is bonded to intermediate plate 120. Such an embodiment is depicted in FIGS. 2A and 2B. Target material 130 is formed via, e.g., spray deposition, on a substrate 200. Substrate 200 may include or consist essentially of any rigid material capable of supporting target material 130 and withstanding the moderate spray-deposition temperatures during formation of target material 130. Examples of substrates 200 include metals or metal alloys such as stainless steel, ceramics, or even wood. As shown in the figures, target material 130 is preferably formed with a conformation complementary to that of the desired intermediate plate 120, e.g., with one or more protrusions 210 complementary to recess(es) 140 in the intermediate plate 120.

As shown in FIG. 2A, substrate 200 may incorporate or have disposed thereon an optional release layer 220 (e.g., an adhesive material and/or other material melting or dissolving at a temperature that is preferably higher than the deposition temperature of target material 130 and lower than the melting point of target material 130) to facilitate post-formation separation of target material 130 from substrate 200. As shown in FIG. 2B, after formation of target material 130 on substrate 200 and/or release layer 210, target material 130 is separated from substrate 200 (by, e.g., dissolution of the release layer 210) and bonded to intermediate plate 120 (as described above and depicted in FIG. 1). While in preferred embodiments, the spray-deposited target material 130 has the final desired size and shape for bonding to intermediate plate 120, in some embodiments the target material 130 is flattened and/or machined after removal from substrate 200 and prior to bonding to intermediate plate 120. As shown in FIG. 2A, the target material 130 may be formed such that protrusions 210 are opposite the interface between substrate 200 (or release layer 220) and target material, in order to facilitate separation at the interface. In other embodiments, substrate 200 incorporates recesses substantially similar to recesses 140 in intermediate plate 120 such that protrusions 210 are formed therein.

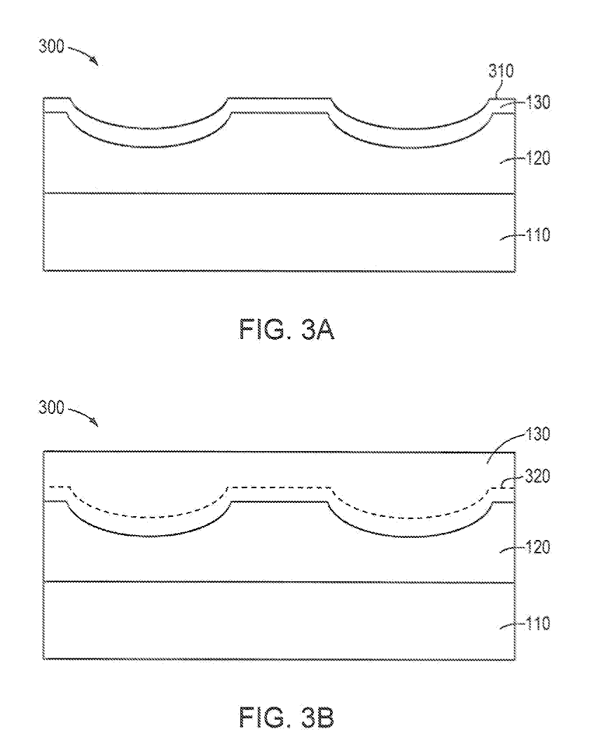

As shown in FIGS. 3A and 3B, embodiments of the present invention may be utilized to rejuvenate used sputtering targets. FIG. 3A depicts a depleted sputtering target 300 in which a significant portion of the target material 130 has been removed during PVD processes, leaving a top surface 310. As shown, top surface 310 may approximately conform to any underlying contours (e.g., recesses 140) in intermediate plate 120. As described above, the presence of recesses 140 in intermediate plate 120 enable the sputtering target to be utilized for a longer interval (with more concomitant removal of target material 130) than a sputtering target without a profiled shape. Sputtering target 300 may incorporate target material 130 and/or intermediate plate 120 that are spray deposited on and/or bonded to backing plate 110, or these materials may be formed via other conventional means.

Rather than depleted target material 130 and/or intermediate plate 120 being removed from bonding plate 110 and/or discarded, additional target material 130 may instead be spray deposited over the depleted target material 130, as shown in FIG. 3B. After this spray deposition, sputtering target may substantially resemble a new sputtering target (e.g., sputtering target 100 described above). In some embodiments, a boundary 320 (e.g., substantially conforming to the pre-rejuvenation surface 310 of sputtering target 300) is present between the regions of the original and the newly deposited target material 130. While the microstructure of the entire target material 130 (both original and newly deposited regions) is preferably substantially constant through its thickness, boundary 320 may be visible during, e.g., high-magnification cross-sectional examination of sputtering target 300. Boundary 320 typically has no impact on the performance or properties of sputtering target 300. As detailed above, the moderate temperatures of the deposition process enable the direct rejuvenation of sputtering target 300 without removal of backing plate 110 and/or intermediate plate 120 due to concerns regarding possible melting or damage thereto.

After formation and/or repair of sputtering targets 100, 300, the sputtering targets may be utilized in PVD to fabricate any number of electronic materials, layers, and/or devices. For example, target material 130 may be sputtered from a sputtering target 100 and deposited on a substrate or device, thus forming a thin film of the target material 130 thereon. Sputtering targets fabricated in accordance with embodiments of the invention may typically be utilized in PVD processes without being subjected to a “burn-in” procedure after formation. As used herein, “burn-in” of a sputtering target refers to removal of a surface layer of material (which may include contaminants and/or deleterious stresses) at a power level (i.e., of a PVD tool) greater than that utilized for typical PVD processes. The burn-in process may even remove material from a larger region (or even substantially the entirety) of the surface of the target than does a typical PVD process.

The terms and expressions employed herein are used as terms of description and not of limitation, and there is no intention, in the use of such terms and expressions, of excluding any equivalents of the features shown and described or portions thereof, but it is recognized that various modifications are possible within the scope of the invention claimed.

What is claimed is:

1. A method of forming a sputtering target, the method comprising:
providing an intermediate plate on a backing plate; and
forming a target material on the intermediate plate,
wherein the intermediate plate has a coefficient of thermal expansion (CTE) between a CTE of the backing plate and a CTE of the target material.

2. The method of claim 1, wherein the intermediate plate is formed on the backing plate by spray deposition.

3. The method of claim 2, wherein the intermediate plate is formed on the backing plate by cold spray.

4. The method of claim 1, wherein the target material is formed on the intermediate plate by spray deposition.

5. The method of claim 4, wherein the target material is formed on the intermediate plate by cold spray.

6. The method of claim 1, wherein providing the intermediate plate comprises bonding the intermediate plate to the backing plate.

7. The method of claim 6, wherein the target material is formed on the intermediate plate prior to the intermediate plate being bonded to the backing plate.

8. The method of claim 7, wherein the target material is formed by spray deposition.

9. The method of claim 8, wherein the target material is formed by cold spray.

10. The method of claim 1, wherein a top surface of the intermediate plate has a profiled surface contour comprising one or more recesses corresponding to regions of high target-material consumption during a physical-vapor-deposition process.

11. The method of claim 1, wherein the intermediate plate substantially prevents warpage of the backing plate due to residual stress in the target material.

12. A sputtering target comprising:
a backing plate comprising a backing-plate material;
a target material disposed over the backing plate, a melting point of the target material exceeding a melting point of the backing plate by at least 500° C.; and
an intermediate plate disposed between the backing plate and the target material, the intermediate plate having a coefficient of thermal expansion (CTE) between a CTE of the backing plate and a CTE of the target material.

13. The sputtering target of claim 12, wherein the target material consists essentially of unmelted metal powder.

14. The sputtering target of claim 12, wherein the intermediate plate consists essentially of unmelted metal powder.

15. The sputtering target of claim 12, wherein the target material is at least one member of the group consisting of: niobium, tantalum, tungsten, molybdenum, zirconium, titanium, and alloys thereof.

16. The sputtering target of claim 12, wherein the intermediate plate comprises an alloy of the backing-plate material and the target material.

17. The sputtering target of claim 12, wherein the target material has a substantially random crystalline texture.

18. The sputtering target of claim 12, wherein the backing-plate material comprises (i) copper, (ii) aluminum, or (iii) an alloy of beryllium with at least one of copper or aluminum.

19. The sputtering target of claim 12, wherein the target material is substantially free of grain-size banding and texture banding.

20. The sputtering target of claim 12, wherein the target material has a substantially uniform equiaxed grain structure and an average grain size less than 44 microns.

21. The sputtering target of claim 12, wherein a top surface of the intermediate plate has a profiled surface contour comprising one or more recesses corresponding to regions of high target-material consumption during a physical-vapor-deposition process.
